(19) United States
(12) Patent Application Publication
(10) Pub. No.: US 2025/0254934 A1
(43) Pub. Date: Aug. 7, 2025

(54) EDGE TERMINATION USING IMPLANT DAMAGE

(71) Applicant: Wolfspeed, Inc., Durham, NC (US)

(72) Inventors: Daniel Cowperthwait, Wake Forest, NC (US); Jae-Hyung Park, Apex, NC (US)

(21) Appl. No.: 18/431,115

(22) Filed: Feb. 2, 2024

(51) Int. Cl. H01L 29/06; H01L 21/04; H01L 29/16; H01L 29/66; H01L 29/872

(52) U.S. Cl. CPC H10D 62/107; H01L 21/0465; H10D 8/051; H10D 8/60; H10D 62/8325

(57) ABSTRACT

A semiconductor device includes a semiconductor substrate having a first conductivity type and a drift layer on the semiconductor substrate. The semiconductor device includes an active region and an edge termination region adjacent at least a portion of the active region. The edge termination region includes a damage region in the drift layer that is formed by implantation of electrically active ions into the drift layer. Related methods are also disclosed.

### FIELD

The present disclosure relates to power semiconductor devices and, more particularly, to power semiconductor devices having an edge termination region formed from implant damage.

### BACKGROUND

Power semiconductor devices are used to carry large currents and support high voltages. A wide variety of power semiconductor devices are known in the art including, for example, power Metal Oxide Semiconductor Field Effect Transistors (“MOSFET”), Junction Field Effect Transistors (“JFET”), bipolar junction transistors (“BJTs”), Insulated Gate Bipolar Transistors (“IGBT”), Schottky diodes, Junction Barrier Schottky (“JBS”) diodes, merged p-n Schottky (“MPS”) diodes, Gate Turn-Off Transistors (“GTO”), MOS-controlled thyristors and various other devices. These power semiconductor devices are generally fabricated from monocrystalline silicon semiconductor material, or, more recently, from silicon carbide or gallium nitride based semiconductor materials.

Power semiconductor devices can have a lateral structure or a vertical structure. In a device having a lateral structure, the terminals of the device (e.g., the drain, gate and source terminals for a power MOSFET device) are on the same major surface (i.e., top or bottom) of a semiconductor layer structure. In contrast, in a device having a vertical structure, at least one terminal is provided on each major surface of the semiconductor layer structure (e.g., in a vertical MOSFET device, the source may be on the top surface of the semiconductor layer structure and the drain may be on the bottom surface of the semiconductor layer structure). The semiconductor layer structure may or may not include an underlying substrate. Herein, the term “semiconductor layer structure” refers to a structure that includes one or more semiconductor layers such as semiconductor substrates and/or semiconductor epitaxial layers.

A conventional silicon carbide power device typically has a silicon carbide (SIC) substrate, such as a silicon carbide wafer having a first conductivity type (e.g., an n-type substrate), on which an epitaxial layer structure having the first conductivity type (e.g., n-type) is formed. This epitaxial layer structure (which may include one or more separate layers) functions as a drift region of the power semiconductor device. The active region may be formed on and/or in the drift region. The active region acts as a main junction or region for blocking voltage in the reverse bias direction and providing current flow in the forward bias direction. The device may also have an edge termination region adjacent the active region. One or more power semiconductor devices may be formed on the substrate, and each power semiconductor device will typically have its own edge termination. After the substrate is fully formed and processed, the substrate may be diced to separate the individual edge-terminated power semiconductor devices if multiple devices are formed on the same substrate. The power semiconductor devices may have a unit cell structure in which the active region of each power semiconductor device includes a large number of individual unit cells that are disposed in parallel to each other and that together function as a single power semiconductor device.

Manufacturing power devices on SiC wafers can be expensive because it requires special equipment and processes due to the unique physical and chemical properties of SiC. Such processes include high-temperature ion implantation and high-temperature annealing. High-temperature implantation reduces lattice damage during high dose implantation. Post-implantation annealing is carried out at 1600-1700 degrees Celsius to achieve reasonable lattice recovery and high electrical activation. These processes require specially adapted equipment that are expensive due to high demand and long lead times.

### SUMMARY

A semiconductor device according to some embodiments includes a semiconductor substrate having a first conductivity type and a drift layer on the semiconductor substrate. The semiconductor device includes an active region and an edge termination region adjacent at least a portion of the active region. The edge termination region includes a damage region in the drift layer that is formed by implantation of electrically active ions into the drift layer.

In some embodiments, the implantation of electrically active ions generates crystal lattice damage to the drift layer. The crystal lattice damage may form a junction-less edge termination region.

In some embodiments, the first conductivity type includes a n-type conductivity.

In some embodiments, the semiconductor substrate includes one of silicon carbide (SiC), zinc oxide, gallium oxide, or gallium nitride. When the semiconductor substrate includes SiC, the semiconductor substrate may include one of 4H—SiC or 6H—SiC.

In some embodiments, the edge termination region is formed without annealing at a temperature greater than 1000 degrees Fahrenheit. In some other embodiments, the edge termination region is formed without annealing at a temperature greater than 1500 degrees Fahrenheit.

In some embodiments, the electrically active ions include aluminum ions. In some of these embodiments, the aluminum ions are implanted with a dose of 1.5E15 cm⁻².

In some embodiments, the ions are implanted at an implant energy of at least about 80 keV.

In some embodiments, the semiconductor device further includes a metal contact on the drift layer that is adjacent the active region of the semiconductor device. In some of these embodiments, the metal contact is further adjacent a portion of the edge termination region.

In some embodiments, the semiconductor device further includes a passivation layer on the drift layer and is adjacent a portion of the edge termination region.

In some embodiments, the semiconductor device includes a plurality of damage regions in the drift layer beneath the metal contact. The plurality of damage regions may be in contact with the metal contact.

In some embodiments, the damage region is characterized by having a therma-wave unit (TWU) value of greater than 5000 TWU. In some embodiments, a ratio of a TWU value for the damage region relative to a TWU value for an unimplanted portion of the drift layer is greater than 50.

A method of forming a semiconductor device according to some embodiments includes providing a semiconductor substrate having a first conductivity type, forming a drift layer on the semiconductor substrate, and implanting electrically active ions into the drift layer to form an the edge termination region in the drift layer adjacent at least a portion of an active region of the semiconductor device.

In some embodiments, implanting the electrically active ions generates crystal lattice damage to the drift layer. In some of these embodiments, the crystal lattice damage forms a junction-less edge termination region.

In some embodiments, the edge termination region is formed without annealing at a temperature greater than 1500 degrees Fahrenheit.

In some embodiments, the electrically active ions include aluminum ions. In some of these embodiments, the aluminum ions are implanted with a dose of 1.5E15 cm⁻².

In some embodiments, the aluminum ions are implanted at an implant energy of at least about 80 keV.

In some embodiments, the method of forming a semiconductor device according to some embodiments further includes forming an implant mask on the drift layer prior to implantation of the electrically active ions.

In some embodiments, the method of forming a semiconductor device according to some embodiments further includes forming a metal contact on the drift layer after implantation of the electrically active ions, wherein the metal contact is adjacent the active region of the semiconductor device. In some of these embodiments, the metal contact is further adjacent at least a portion of the edge termination region. In some of these embodiments, the metal contact is further adjacent at least a portion of the edge termination region.

In some embodiments, the method of forming a semiconductor device according to some embodiments further includes forming a passivation layer on the drift layer and is adjacent a portion of the edge termination region.

### BRIEF DESCRIPTION OF THE DRAWINGS

FIGS. 1A-C illustrate operations for using implantation damage to form a semiconductor device, according to some embodiments;

FIGS. 2A-C illustrate operations for using implantation damage to form a semiconductor device with a metal contact adjacent a portion of an edge termination region, according to some embodiments;

FIGS. 3A-D illustrate operations for using implantation damage to form a semiconductor device with a passivation layer adjacent a portion of the edge termination region, according to some embodiments;

FIG. 4 illustrates a junction barrier Schottky (JBS) semiconductor device that used implantation damage, according to some embodiments;

FIG. 5A illustrates variable gauge analysis for maximum reverse current of a process of record (POR) and a present process with no activation for a device with a rated blocking voltage of 1200V, according to some embodiments; and

FIG. 5B illustrates variable gauge analysis for forward voltage of the POR and the present process with no activation, according to some embodiments.

### DETAILED DESCRIPTION OF EMBODIMENTS

Embodiments of the inventive concepts will now be described in connection with the accompanying drawings.

Some embodiments of the present disclosure is directed to a power semiconductor device that may provide the advantage of lowering production cost to manufacture power devices that may neither employ high-temperature ion implantation nor high-temperature annealing. This may be possible by engineered crystal damage to the epitaxial layer that may function as highly resistive layers that distribute and lower the electric field crowding at the device periphery.

The breakdown voltage of a vertical power device is generally limited by edge breakdown due to field crowding at the periphery of the vertical power device. Most present schemes require an element of PN junction. In present SiC semiconductor technology, a p-type region is formed by implantation and activation, usually at high temperatures. However, the present disclosure uses crystal damage induced by implantation instead of using PN junction-based edge termination. This may reduce or remove a need for SiC-specific equipment and processes. It may also significantly reduce the processing time.

There are materials, from which power devices can be fabricated, where high-temperature dopant activation via annealing is not an option. Thus, junction formation is not viable. In such instances, one would have to resort to an edge termination scheme that does not depend on junction formation. Some embodiments of the present disclosure provide a path to forming a junction-less edge termination.

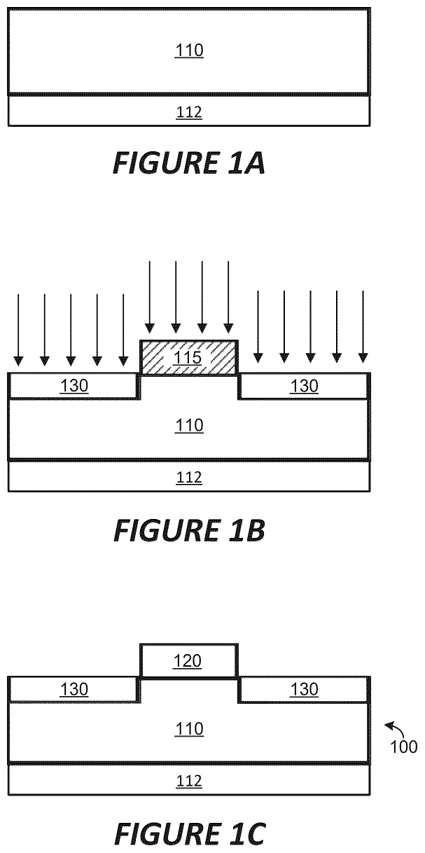

FIGS. 1A-C illustrate operations for using implantation damage to form a semiconductor device 100, according to some embodiments. While a Schottky diode is shown in the operations of FIGS. 1A-B (and other figures below), it will be appreciated that similar operations may be used in the fabrication of other types of devices such as integrated Schottky diode-MOSFET devices.

Referring to FIG. 1A, a semiconductor substrate 112 having a first conductivity type is provided. In some embodiments, the first conductivity type includes a n-type conductivity.

In some embodiments, the semiconductor substrate 112 comprises one of silicon carbide (SiC), zinc oxide, gallium oxide, or gallium nitride. In some embodiments, when the semiconductor substrate 112 includes SiC, the semiconductor substrate 112 has a 2H, 4H, 6H, or 3C polytype. In some additional or alternative embodiments, the semiconductor substrate 112 may have an off-angle orientation of about 0 to 5 degrees.

A drift layer 110 is formed on the semiconductor substrate 112. In some embodiments, the drift layer 110 may be doped with a net doping concentration of less than about 2E16 cm-3.

Referring to FIG. 1B, an implant mask 115 is formed on the drift layer 110. The implant mask 115 is formed on the drift layer 110 to form opening(s) for implantation of electrically active ions into the drift layer 110. The implant mask 115 is formed on the drift layer 110 prior to implantation of electrically active ions.

While a single implant mask 115 is illustrated in FIG. 1B, a plurality of implant masks may be used herein for create opening(s) for implantation of electrically active ions into the drift layer.

The electrically active ions are implanted into the drift layer 110 to form an edge termination region 130 in the drift layer adjacent at least a portion of an active region of the semiconductor device 100. The implanting of the electrically active ions may generate crystal lattice damage to the drift layer 110. The crystal lattice damage may form a junction-less edge termination region.

The implantation of electrically active ions into the drift layer 110 to form the edge termination region 130 may cause edge termination region to exhibit lattice damage relative to the non-implanted portions of the drift layer 110. Lattice damage in a semiconductor wafer may be characterized by modulated reflectance measurements in a Therma-Wave Inc. TP-300 device. In particular, lattice damage may be characterized using a TP-300 in therma-wave units (TWU), which is an arbitrary unit of modulated reflectance which is proportional to the damage produced by the implanted ions. In some embodiments, the edge termination region 130 may be characterized by a TW value greater than 5,000 TWU for implants performed at elevated temperature (e.g., greater than 450C), while non-implanted or annealed portions of the drift layer 110 may have a TWU value less than 100 TWU. In some cases, the edge termination region 130 may be characterized by a TW value between about 5,000 TWU and 50,000 TWU. In some embodiments, the edge termination region 130 may be characterized by a TW value greater than 10,000 TWU, in some cases greater than 20,000 TWU, and in some cases greater than 30,000 TWU. For example, for room temperature implants, the implanted region may be characterized by a TWU of greater than 45,000 TWU. In some cases, a ratio of the TWU measurement for the edge termination region 130 relative to the TWU measurement of non-implanted portions of the drift layer 110 may be between about 50 and 400. In some cases, the ratio may be greater than 100, in some cases greater than 200 and in some cases greater than 300.

The edge termination region may be formed without high-temperature implantation and annealing. In some embodiments, the edge termination region is formed without annealing at a temperature greater than 1000 degrees Fahrenheit. In some other embodiments, the edge termination region is formed without annealing at a temperature greater than 1500 degrees Fahrenheit.

The electrically active ion may include any type of electrically active ions. In some embodiments, the electrically active ions include aluminum (Al) ions. In these embodiments, the Al ions are implanted with a dose of 1.5E15 cm⁻². Additionally, or alternatively, the Al ions are implanted at an implant energy of at least about 80 keV.

In some embodiments, the electrically active ions include, for example, nitrogen, phosphorus, boron, vanadium and/or arsenic. Other ions may be used, such as actinium, yttrium, lanthanum, scandium, etc.

Referring to FIG. 1C, a metal contact 120 is formed on the drift layer 110 after implantation of the electrically active ions. The metal contact is adjacent the active region of the semiconductor device 100.

These operations illustrated in FIGS. 1A-C may form a semiconductor device (e.g., semiconductor device 100 illustrated in FIG. 1C) including the semiconductor substrate 112 having the first conductivity type and the drift layer 110 on the semiconductor substrate 112. The semiconductor device 100 includes the active region and the edge termination region 130 adjacent at least a portion of the active region. Additionally, the edge termination region 130 includes a damage region in the drift layer 110 that is formed from the implantation of the electrically active ions into the drift layer 110.

In some embodiments, the semiconductor device further includes a metal contact (e.g., metal contact 120 of FIG. 1C) on the drift layer that is adjacent the active region of the semiconductor device.

In these embodiments, the damaged region are formed on the top surfaces of the drift layer and are not covered by the metal contact. In this embodiment, the metal contact is not adjacent a portion of the edge termination region.

In some embodiments, the metal contact is a Schottky metal.

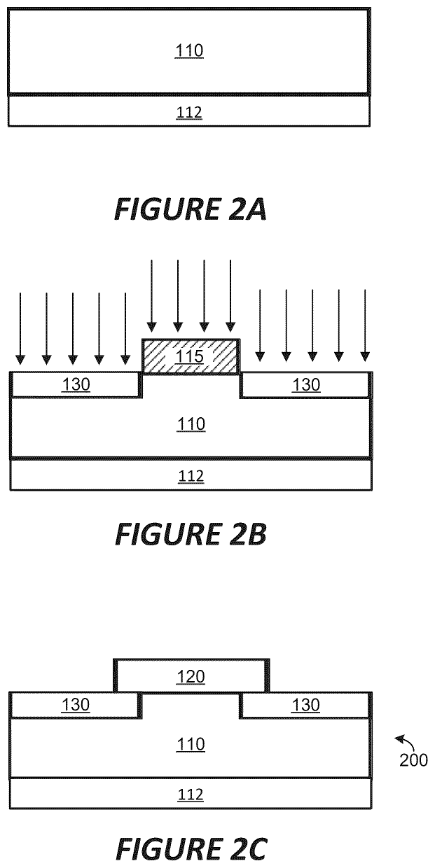

FIGS. 2A-C illustrate operations for using implantation damage to form a semiconductor device 200 with a metal contact 120 adjacent a portion of an edge termination region, according to some embodiments.

The operations in FIGS. 2A-B may be similar to the operations performed in FIGS. 1A-B.

Referring to FIG. 2C, a metal contact 120 is formed on the drift layer 110 after implantation of the electrically active ions. In these embodiments, the metal contact 120 overlaps a portion of both edge termination region 130. Additionally, the metal contact overlaps an active region of the semiconductor device 200. Therefore, the metal contact 120 is adjacent the active region of the semiconductor device 200 and a portion of both edge termination region 130.

These operations illustrated in FIGS. 2A-C may form a semiconductor device (e.g., semiconductor device 200 illustrated in FIG. 2C) including the semiconductor substrate 112 having the first conductivity type and the drift layer 110 on the semiconductor substrate 112. The semiconductor device 200 includes the active region and the edge termination region 130 adjacent at least a portion of the active region. Additionally, the edge termination region 130 includes a damage region in the drift layer 110 that is formed from the implantation of the electrically active ions into the drift layer 110.

In some of these embodiments, the semiconductor device further includes a metal contact (e.g., metal contact 120 of FIG. 2C) that is adjacent an active region of the semiconductor device and is further adjacent a portion of the edge termination region.

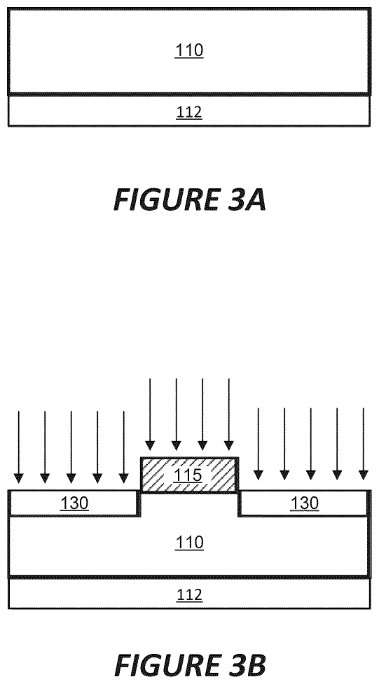

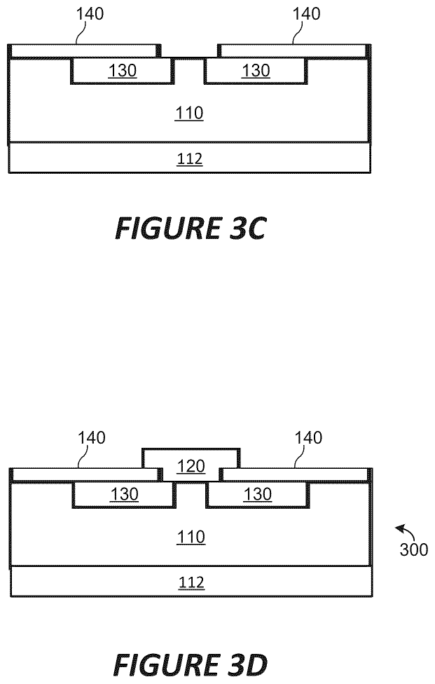

FIGS. 3A-D illustrate operations for using implantation damage to form a semiconductor device 300 with a passivation layer 140 adjacent a portion of the edge termination region 130, according to some embodiments.

The operations of FIGS. 3A-B may be similar to the operations performed in FIGS. 1A-B.

Referring to FIG. 3C, the passivation layer 140 is formed on the drift layer and is adjacent a portion of the edge termination region 130.

In this manner, a passivation scheme is utilized. In the case of thermal oxidation, the passivation may consume some amount of drift layer 110 along with the damaged layer (e.g., edge termination region 130). This may control the thickness of the edge termination region 130. In some embodiments, the edge termination region 130 may include an amorphous layer. In these embodiments, the passivation consuming some amount of the edge termination region 130 adjusts the sheet resistance of the amorphous layer.

Referring to FIG. 3D, a metal contact 120 is formed on the drift layer 110 after implantation of the electrically active ions and after the passivation layer 140 is formed. In these embodiments, the metal contact 120 is adjacent an active region of the semiconductor device 300, a portion of both edge termination region 130, and a portion of the passivation layer 140.

These operations illustrated in FIGS. 3A-D may form a semiconductor device (e.g., semiconductor device 300 illustrated in FIG. 3D) including the semiconductor substrate 112 having the first conductivity type and the drift layer 110 on the semiconductor substrate 112. The semiconductor device 300 includes the active region and the edge termination region 130 adjacent at least a portion of the active region. Additionally, the edge termination region 130 includes a damage region in the drift layer 110 that is formed from the implantation of the electrically active ions into the drift layer 110.

Additionally, in some embodiments, the semiconductor device includes a passivation layer on the drift layer that is adjacent a portion of the edge termination region. In these embodiments, the semiconductor device further includes a metal contact that is adjacent the active region of the semiconductor device, a portion of the edge termination region, and a portion of the passivation layer.

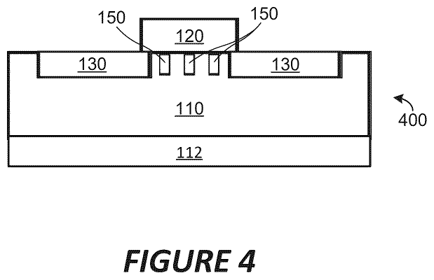

FIG. 4 illustrates a semiconductor device 400 that uses implantation damage, according to further embodiments.

For example, to form the semiconductor device 400, similar operations to the operations shown in FIGS. 1A-B may be used. However, in addition to forming the edge termination region 130, a plurality of additional damage regions 150 are formed in the drift layer 110 beneath the metal contact 120. The damage regions 150 may be formed at a surface of the drift layer 110 and may be in contact with the metal contact 120.

The damage regions 150 may provide additional protection to the metal-semiconductor junction between the metal contact 120 and the drift layer 110 under reverse bias conditions in a manner similar to the operation of junction barrier Schottky (JBS) regions.

For example, implant masks may be used to create opening(s) for implantation of p-type dopants or electrically active ions into the drift region to form the damage regions 150 in the drift region at the same time as the edge termination region 130 is formed. Then, a metal contact 120 may be formed on the drift layer 110.

In some embodiments, the metal contact 120 is adjacent an active region of the semiconductor device 400 and the damage regions 150. In some additional embodiments, the metal contact 120 is further adjacent a portion of an edge termination region 130.

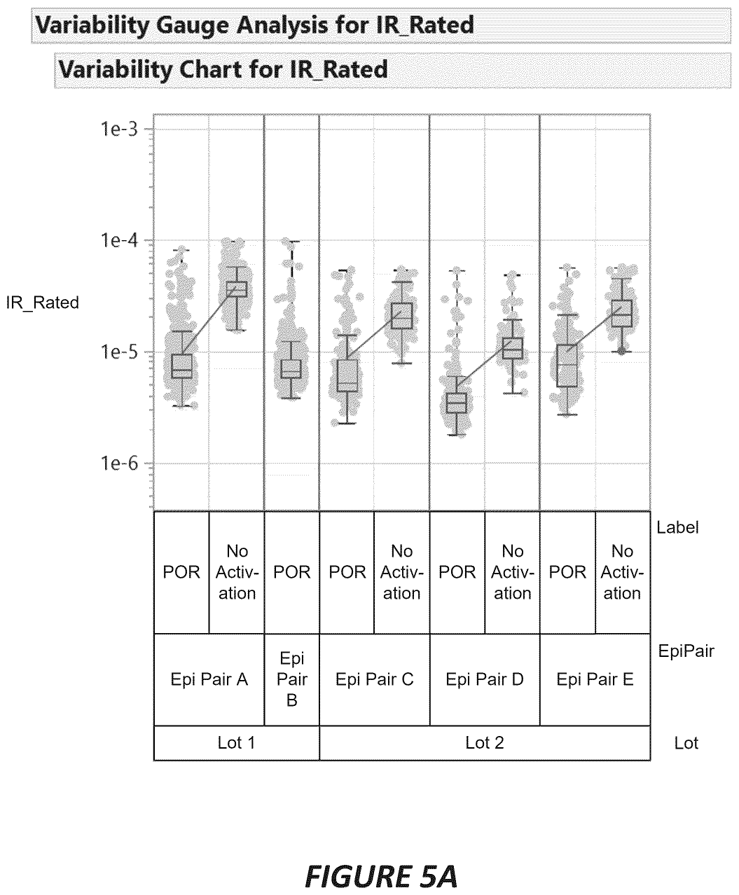

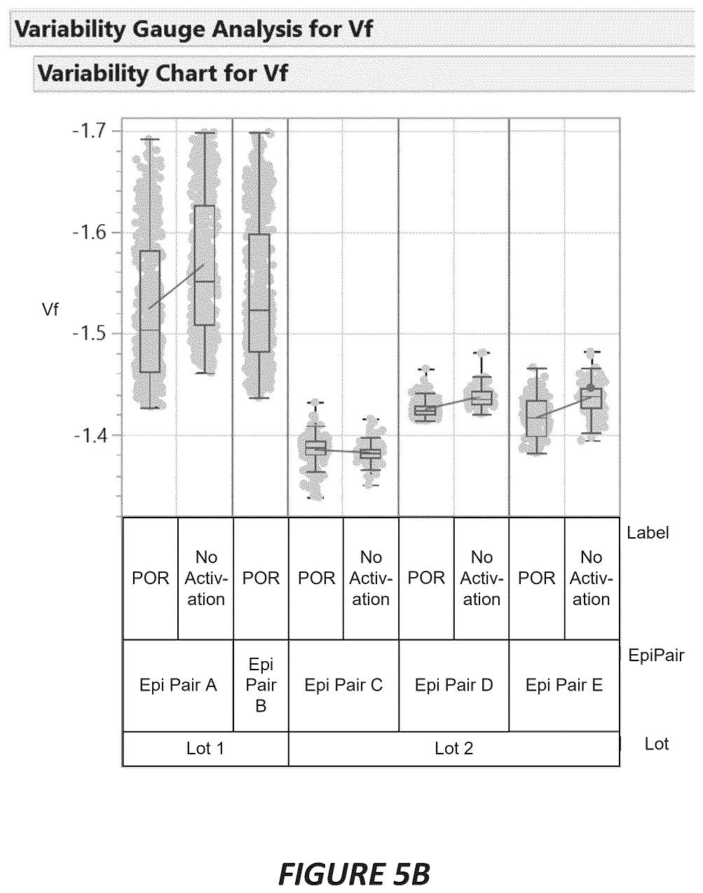

FIG. 5A illustrates variable gauge analysis for maximum reverse current of a conventional process (with activated dopants) and a process according to some embodiments with no activation for a device with a rated blocking voltage of 1200V. FIG. 5B illustrates variable gauge analysis for forward voltage of the conventional (activated) process and a process with no activation, according to some embodiments.

The use of neutral atomic specie such as Argon (Ar) to induce amorphous epitaxial layers that aid in distributing the electric field crowding has been described, including an Ar implantation with a dose close to 1.0E+15 cm⁻² at 30 keV implantation energy. The present disclosure, as shown in

FIGS. 5A-B, shows proper blocking, though elevated in leakage compared to the conventional (activated) process, at a breakdown voltage above 1200V. 80 keV Al implantation with a dose of 1.5E+15 was used. However, it should be noted that the implantation is not limited to such a dose and energy level.

The data in FIGS. 5A-B shows ‘no activation’ splits that demonstrate the feasibility of using Al implantation as opposed to Ar. From there, one can see that this type of methodology may extend to other species of atoms as long as they introduce appropriate amount of lattice damage.

The above types of edge termination scheme, although it may differ in atomic specie, implantation energy and dose, can potentially extend to any power device where implantation can induce lattice damage and where high-temperature annealing is not possible.

Such potential other semiconductor systems may include Zinc Oxide, Gallium Oxide, Gallium Nitride, etc.

Not illustrated in the above semiconductor devices, but may be included in the semiconductor devices (e.g., semiconductor devices 100, 200, 300, and 400), is a backside metal layer (e.g., a drain contact) that is deposited onto the bottom of the semiconductor substrate (e.g., semiconductor substrate 112). The backside metal layer may be a metal (non-limiting examples include nickel, tantalum, and/or titanium) to complete the semiconductor device structure.

While in the description above, the example embodiments are described with respect to semiconductor devices that have n-type substrates and channels in n-type portions of the drift layers, it will be appreciated that opposite conductivity type devices may be formed by simply reversing the conductivity of the n-type and p-type layers in each of the above embodiments. Thus, it will be appreciated that the present disclosure covers both n-type and p-type devices. It will likewise be appreciated that typically each power semiconductor device formed according to the ion implantation techniques disclosed herein will comprise a plurality of individual devices that are disposed in parallel in a unit cell structure.

Embodiments have been described above with reference to the accompanying drawings, in which embodiments are shown. It will be appreciated, however, that the inventive concepts may, however, be embodied in many different forms and should not be construed as limited to the embodiments set forth above. Rather, these embodiments are provided so that this disclosure will be thorough and complete, and will fully convey the scope of the inventive concepts to those skilled in the art. Like numbers refer to like elements throughout.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the present inventive concepts. The term “and/or” includes any and all combinations of one or more of the associated listed items.

The terminology used herein is for the purpose of describing particular embodiments only and is not intended to be limiting of the inventive concepts. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the inventive concepts are described herein with reference to cross-section illustrations that are schematic illustrations of idealized embodiments (and intermediate structures) of the inventive concepts. The thickness of layers and regions in the drawings may be exaggerated for clarity. Additionally, variations from the shapes of the illustrations as a result, for example, of manufacturing techniques and/or tolerances, are to be expected.

Some embodiments are described with reference to semiconductor layers and/or regions which are characterized as having a conductivity type such as n-type or p-type, which refers to the majority carrier concentration in the layer and/or region. Thus, n-type material has a majority equilibrium concentration of negatively charged electrons, while p-type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation, the scope of the inventive concepts being set forth in the following claims.

1. A semiconductor device, comprising:
a semiconductor substrate having a first conductivity type; and
a drift layer on the semiconductor substrate;
wherein the semiconductor device comprises an active region and an edge termination region adjacent at least a portion of the active region;
wherein the edge termination region comprises a damage region in the drift layer that is formed by implantation of electrically active ions into the drift layer.

2. The semiconductor device of claim 1, wherein the implantation of electrically active ions generates crystal lattice damage to the drift layer.

3. The semiconductor device of claim 2, wherein the crystal lattice damage forms a junction-less edge termination region.

4. The semiconductor device of claim 1, wherein the first conductivity type comprises a n-type conductivity.

5. The semiconductor device of claim 1, wherein the semiconductor substrate comprises one of silicon carbide (SiC), zinc oxide, gallium oxide, or gallium nitride.

6. The semiconductor device of claim 5, wherein, when the semiconductor substrate comprises SiC, the semiconductor substrate comprises one of 4H—SiC or 6H—SiC.

7. The semiconductor device of claim 1, wherein the edge termination region is formed without annealing at a temperature greater than 1000 degrees Fahrenheit.

8. The semiconductor device of claim 1, wherein the edge termination region is formed without annealing at a temperature greater than 1500 degrees Fahrenheit.

9. The semiconductor device of claim 1, wherein the electrically active ions comprise aluminum ions.

10. The semiconductor device of claim 9, wherein the aluminum ions are implanted with a dose of 1.5E15 cm⁻².

11. The semiconductor device of claim 1, wherein the aluminum ions are implanted at an implant energy of at least about 80 keV.

12. The semiconductor device of claim 1, further comprising:
a metal contact on the drift layer that is adjacent the active region of the semiconductor device.

13. The semiconductor device of claim 12, wherein the metal contact is further adjacent a portion of the edge termination region.

14. The semiconductor device of claim 12, further comprising:
a passivation layer on the drift layer and is adjacent a portion of the edge termination region.

15. The semiconductor device of claim 12, further comprising:
a plurality of damage regions in the drift layer beneath the metal contact.

16. The semiconductor device of claim 15, wherein the plurality of damage regions are in contact with the metal contact.

17. The semiconductor device of claim 1, wherein the damage region comprises a region having un-annealed crystal lattice damage due to ion implantation.

18. The semiconductor device of claim 17, wherein the damage region is characterized by having a therma-wave unit (TWU) value of between about 5000 TWU and 50,000 TWU.

19. The semiconductor device of claim 18, wherein a ratio of a TWU value for the damage region relative to a TWU value for an unimplanted portion of the drift layer is between about 50 and 400.

20. A method of forming a semiconductor device, comprising:
providing a semiconductor substrate having a first conductivity type;
forming a drift layer on the semiconductor substrate; and
implanting electrically active ions into the drift layer to form an edge termination region in the drift layer adjacent at least a portion of an active region of the semiconductor device.

21. The method of claim 20, wherein implanting the electrically active ions generates crystal lattice damage to the drift layer.

22. The method of claim 21, wherein the crystal lattice damage forms a junction-less edge termination region.

23. The method of claim 20, wherein the first conductivity type comprises a n-type conductivity.

24. The method of claim 23, wherein the semiconductor substrate comprises one of silicon carbide (SiC), zinc oxide, gallium oxide, or gallium nitride.

25. The method of claim 24, wherein, when the semiconductor substrate comprises SiC, the semiconductor substrate comprises 4H—SiC or 6H—SiC.

26. The method of claim 20, wherein the edge termination region is formed without being heated to a temperature greater than 1000 degrees Fahrenheit after implantation of the electrically active ions.

27. The method of claim 20, wherein the edge termination region is formed without being heated to a temperature greater than 1500 degrees Fahrenheit after implantation of the electrically active ions.

28. The method of claim 20, wherein the electrically active ions comprise aluminum ions.

29. The method of claim 28, wherein the aluminum ions are implanted with a dose of 1.5E15 cm⁻².

30. The method of claim 20, wherein the aluminum ions are implanted at an implant energy of at least about 80 keV.

31. The method of claim 20, further comprising:
forming an implant mask on the drift layer prior to implantation of the electrically active ions.

32. The method of claim 20, further comprising:
forming a metal contact on the drift layer after implantation of the electrically active ions, wherein the metal contact is adjacent the active region of the semiconductor device.

33. The method of claim 32, wherein the metal contact is further adjacent a portion of the edge termination region.

34. The method of claim 32, further comprising:
forming a passivation layer on the drift layer and is adjacent a portion of the edge termination region.

35. The method of claim 32, further comprising:
forming a plurality of damage regions in the drift layer beneath the metal contact.

36. The method of claim 32, wherein the plurality of damage regions are in contact with the metal contact.

37. The method of claim 20, wherein the semiconductor device is formed without being heated to a temperature greater than 1000 degrees Fahrenheit following implantation of the electrically active ions to form the edge termination layer.

38. The method of claim 20, wherein the semiconductor device is formed without being heated to a temperature greater than 1500 degrees Fahrenheit following implantation of the electrically active ions to form the edge termination layer.

39. The method of claim 20, wherein the edge termination region is characterized by having a therma-wave unit (TWU) value of between about 5000 TWU and 50,000 TWU.

40. The semiconductor device of claim 39, wherein a ratio of a TWU value for the edge termination region relative to a TWU value for an unimplanted portion of the drift layer is between about 50 and 400.
